(19) United States
(12) Patent Application Publication
(10) Pub. No.: US 2006/0170073 A1
(43) Pub. Date: Aug. 3, 2006

(54) Capacitor with high breakdown field

(75) Inventor: Emmanuel Defay, Voreppe (FR)

Correspondence Address: OLIFF & BERRIDGE, PLC, P.O. BOX 19928, ALEXANDRIA, VA, 22320, US

(73) Assignee: Commissariat a l'Energie Atomique, Paris (FR)

(21) Appl. No.: 11/336,763

(22) Filed: Jan. 23, 2006

(30) Foreign Application Priority Data
Feb. 1, 2005 (FR) 0500981

(51) Int. Cl. H01L 29/94

(52) U.S. Cl. 257/532; 257/295; 257/310; 257/E27.104

(57) ABSTRACT

The capacitor is a thin-film capacitor comprising two metal electrodes separated by a dielectric. The dielectric is formed by superposition of at least two sub-layers of preferably perovskite-based dielectric material. Two adjacent superposed dielectric sub-layers are separated by an electrically insulated metal intermediate layer, for example made of platinum. Using very thin dielectric sub-layers, preferably with a thickness of less than 20 nm, separated from one another by metal intermediate layers enables the increase of the breakdown field and the reduction of the leakage currents linked to a reduction of the thickness of the dielectric to be transposed to the level of the capacitor, while preserving a reasonable working field.

### BACKGROUND OF THE INVENTION

The invention relates to a thin-film capacitor comprising two electrodes separated by a dielectric formed by superposition of at least two sub-layers of dielectric material, two adjacent superposed dielectric sub-layers being separated by an electrically insulated metal intermediate layer.

### STATE OF THE ART

Thin-film capacitors, very extensively used in microelectronics, conventionally comprise two electrodes 1 and 2 separated by a dielectric 3 (FIG. 1).

It is increasingly sought to reduce the dimensions of the components whilst preserving the same properties. In the case of integrated capacitors, the surface capacitance C has to be increased to be able to achieve this. However, when the dielectric is formed by a thin layer of dielectric material, the surface capacitance C is given by the formula:
C=ε₀εᵣS/e
where
S is the surface of the electrodes 1 and 2 facing one another, in the case of a flat capacitor,
ε₀ is the dielectric constant of the vacuum,
εᵣ is the relative dielectric constant of the material forming the layer of dielectric material, and
e is the thickness of the dielectric layer.

It is therefore possible to adjust the three parameters S, e and εᵣ to increase the surface capacitance of a capacitor.

However, increasing the surface S runs contrary to the objective sought for, which is to reduce the dimensions of the component. It is however possible to increase this surface artificially by using non-planar structures. Fabrication of such structures is complex and requires expensive equipment.

Reducing the thickness e of the dielectric layer is limited by the occurrence of large leakage currents when the thickness becomes very small and by an increased sensitivity of the fabrication technology.

To increase the dielectric constant εᵣ, which is typically 4 for silicon oxide (SiO₂), the dielectric the most frequently used in microelectronics, it has been proposed to use other dielectric materials, more particularly perovskite-based materials, the relative dielectric constant whereof can reach 1000.These dielectric materials are in particular Pb(Zr,Ti)O₃ also called PZT, (Pb,La)(Zr,Ti)O₃ also called PLZT, Pb(Mg,Nb,Ti)O₃ also called PMNT, (Ba,Sr)TiO₃ also called BST, SrTiO₃ also called STO, BaTiO₃ also called BTO, and PbTiO₃ also called PTO. However, it has been observed that the higher the dielectric constant of the materials, the weaker their breakdown field and the higher the leakage currents.

To overcome this drawback, it has been proposed, in particular in Patent applications US-A-2003/0096473 and US-A-2003/0184952, to form a multi-layer dielectric with an alternation of different dielectric materials and to arrange an amorphous dielectric layer at the interfaces with the electrodes. Associating a layer of dielectric material with a high permittivity and a weak breakdown field and a layer of dielectric material with a low permittivity and a strong breakdown field in particular enables a compromise between these two features to be achieved. Moreover, the amorphous material interface enables the increase of leakage currents due to the polycrystalline structure of most very high permittivity materials to be counteracted.

Furthermore, the document JP-A-01244602 describes a thin-film capacitor of small size nevertheless having a large capacitance and a high dielectric strength. It comprises an alternation of polyimide dielectric layers and of aluminium conducting layers between the capacitor electrodes. In this type of capacitor, the metal layers essentially have the function of enabling the resin constituting the dielectric layers to be secured, to enable a sufficient overall thickness of dielectric to be obtained. The breakdown voltage of the capacitor is in fact proportional to the total thickness of dielectric, and therefore for sub-layers of predetermined thickness, proportional to their number.

### OBJECT OF THE INVENTION

The object of the invention is to provide a capacitor not presenting the drawbacks of known capacitors and, more particularly, a capacitor of reduced size having properties at least equivalent to those of known capacitors.

According to the invention, this object is achieved by a capacitor according to the appended claims and more particularly by the fact that the dielectric material has a dielectric constant greater than 50 and a breakdown field which increases greatly below a certain thickness.

According to one development of the invention, the dielectric material is perovskite-based and each sub-layer of dielectric material has a thickness smaller than or equal to 50 nm.

### BRIEF DESCRIPTION OF THE DRAWINGS

Other advantages and features will become more clearly apparent from the following description of particular embodiments of the invention given as non-restrictive examples only and represented in the accompanying drawings in which:

FIG. 1 schematically illustrates a capacitor according to the prior art.

FIGS. 2 and 3 schematically represent two alternative embodiments of a capacitor according to the invention.

FIG. 4 illustrates the variations of the breakdown field versus the dielectric thickness, in the case of an STO type dielectric.

### DESCRIPTION OF PARTICULAR EMBODIMENTS

The capacitor according to the invention makes use of the fact that certain dielectric materials having a dielectric constant higher than 50, in particular dielectrics with perovskite structure, have a leakage current that decreases and a breakdown field that increases considerably when their thickness decreases below a certain thickness, more particularly below 50 nm for perovskites.

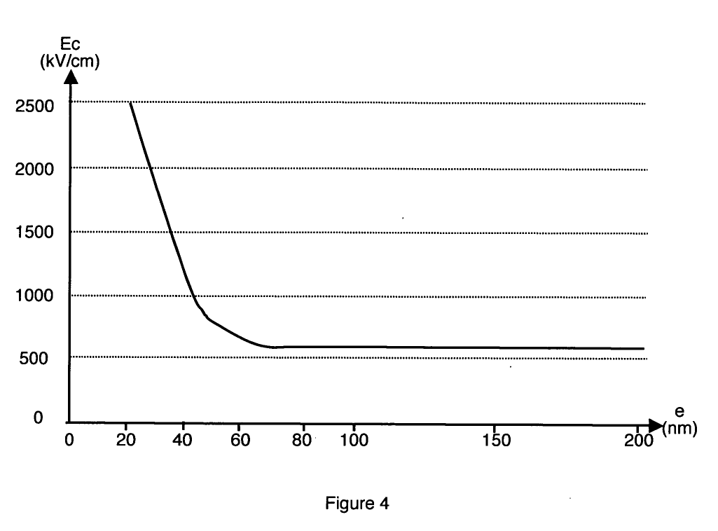

This is illustrated in FIG. 4, for an STO-based dielectric. This figure in fact represents the experimentally measured values of the breakdown field Ec versus the thickness e of an STO layer arranged between two platinum electrodes each having a thickness of 100 nm. Whereas the breakdown field is relatively constant (about 600 kV/cm) above a thickness of 60 nm, it starts to increase below this value, reaching in particular 800 kV/cm for 50 nm, and increases very strongly below 50 nm to reach a value of more than 2000 kV/cm around 20 nm.

All perovskite-base dielectrics present a large increase of the breakdown field when their thickness decreases below a certain threshold. The threshold and the values of the breakdown voltages depend on the type of perovskite involved, but, in all cases, the variation of the breakdown field is very large below 50 nm.

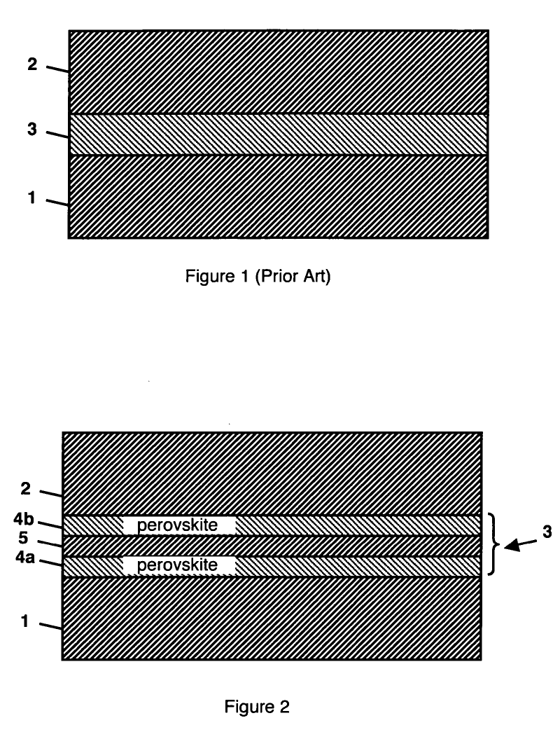

However, merely decreasing the thickness of the dielectric layer 3 of a capacitor according to FIG. 1 would lead to a corresponding increase of the electrical working field.

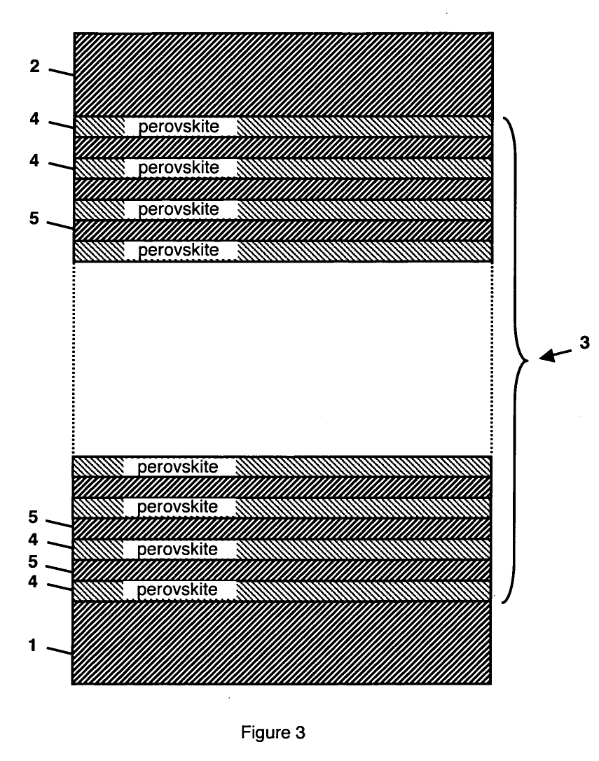

In the particular embodiment of FIG. 2, the dielectric 3 separating the electrodes 1 and 2 of the capacitor is formed by two superposed dielectric sub-layers 4a and 4b of perovskite-based dielectric material, separated by a metal intermediate layer 5. The metal intermediate layer 5 is electrically insulated, i.e. it is not connected to the electrodes 1 and 2. The sub-layers 4a and 4b are thinner than the layer of dielectric material forming the dielectric 3 of the capacitor according to FIG. 1.

Inserting the metal intermediate layer 5 between two adjacent dielectric sub-layers of small thickness enables the advantages linked to reducing the thickness of the perovskite-based dielectric to be kept while at the same time enabling a reasonable electrical working field to be maintained.

The table below enables the properties of three types of capacitors to be compared, all three comprising a perovskite-based dielectric 3 between two platinum electrodes 1 and 2, with a thickness of 100 nm and formed by silicon on insulator technology, i.e. a layer of SiO₂ formed on a silicon substrate:
a capacitor A1 according to FIG. 1, with a single layer of dielectric material, made of STO, having a thickness e of 50 nm,
a capacitor A2, also according to FIG. 1, with a single layer of dielectric material having a thickness e of 20 nm only,

a capacitor A3, according to FIG. 2, with two dielectric sub-layers 4a and 4b, each having a thickness e of 20 nm (i.e. a total thickness Σe of STO of 40 nm) and separated by a metal intermediate layer 5 with a thickness of 20 nm.

| | | | Relative | | Break- |
|---|---|---|---|---|---|
| | Total STO | Breakdown | dielectric | Surface | down |
| Capac- | thickness | field Ec | constant | capacitance | voltage |
| itor | Σe (nm) | (kV/cm) | εᵣ | C nF/mm² | Vc (V) |
| A1 | 50 | 800 | 100 | 20 | 4 |
| A2 | 20 | 2000 | 80 | 40 | 4 |
| A3 | 2 × 20 | 2000 | 80 | 20 | 8 |

Although the relative dielectric constant εᵣ of STO decreases with the thickness, dropping from 100 for a single layer with a thickness of 50 nm to 80 for a layer with a thickness of 20 nm, the surface capacitance C of the capacitor A3, proportional to the relative dielectric constant and inversely proportional to the total thickness Σe of dielectric material,. remains substantially identical to that of the capacitor A1.

At the same time, the increase of the breakdown field Ec, which rises from 800 kV/cm for a dielectric layer of 50 nm to 2000 kV/cm for a 20 nm layer, is sufficiently great for the breakdown voltage Vc (Vc=Ec×Σe) of the capacitor A3 to be twice as large as the breakdown voltage of the capacitors A1 and A2 (8V instead of 4V).

In addition, for a given electric field, the leakage currents are reduced by a factor of about 10 when the thickness of a layer of perovskite-based dielectric material is reduced from 50 nm to 20 nm. The leakage currents of the capacitors A2 and A3 are therefore much lower than those of the capacitor A1.

Thus, for a dielectric 3 of comparable total thickness (50 nm for the single layer of the capacitor A1 and 60 nm for the stacking of two 20 nm dielectric sub-layers separated by a 20 nm metal intermediate layer of the capacitor A3), the capacitor A3 has a capacitance comparable to that of the capacitor A1, but a breakdown voltage Vc that is twice as high and leakage currents reduced by a factor of about 10.

As represented in FIG. 3, the capacitor can comprise a plurality of dielectric layers 4 superposed between the two electrodes 1 and 2, two adjacent superposed dielectric layers 4 being separated by a metal intermediate layer 5. In all cases, a sub-layer of dielectric material 4 is in contact with each of the electrodes 1 and 2, i.e. the first and last layers of the stacking of dielectric sub-layers 4 and metal intermediate layers 5 are formed by dielectric sub-layers 4.

If each dielectric sub-layer 4 has a thickness e, the surface capacitance of a capacitor comprising n dielectric sub-layers 4 is then that of a capacitor having a dielectric with a thickness Σe=ne and a relative dielectric constant εᵣ corresponding to that of a single sub-layer. The breakdown field Ec, which corresponds to the breakdown field of a single sub-layer, of very small thickness, is however much larger than that of a single layer of thickness ne.

The breakdown field of the capacitor and the breakdown voltage of the latter can therefore be substantially improved by the use of dielectric sub-layers 4 made of perovskite, of small thickness e with respect to the total thickness ne of dielectric material, and by two adjacent dielectric sub-layers being separated by a metal intermediate layer 5. The leakage currents are at the same time improved by reducing the thickness of each dielectric layer. The number n of sub-layers 4 and the number n-1 of metal intermediate layers 5 and the respective thicknesses thereof are chosen according to the materials used and to the characteristics required for the capacitor.

For example, the thickness of each dielectric sub-layer 4 and of each metal intermediate layer 5 is preferably comprised between a few nanometers and a few tens of nanometers. Each sub-layer 4 preferably has a thickness less than or equal to 50 nm, for example about 20 nm or even less.

The metal intermediate layers 5 that separate two adjacent sub-layers 4 are electrically insulated, i.e. they are not electrically connected either to the electrodes 1 and 2 or to one another They must however be sufficiently thick to form continuous films preventing any contact between two adjacent dielectric sub-layers. With conventional deposition techniques, a thickness of 20 nm is sufficient.

The electrodes 1 and 2 and the metal intermediate layers must be made from a material compatible with the use of perovskite. They must not suffer damage at the crystallization temperature of perovskite, i.e. at a temperature comprised between 400 and 800° C. Furthermore, the dielectric material must not react with the conducting layers, which excludes the use of aluminum which oxidizes in contact with perovskite. In a preferred embodiment they are made of platinum (Pt) or gold (Au). The electrodes 1 and 2 can also be made of conducting oxide, for example of IrO₂ or RuO₂.

The different layers making up the capacitor can be deposited by any suitable technique enabling thin film deposition to be performed.

It is in particular possible to deposit layers of platinum with a thickness of 10 nm by cathode sputtering. Other techniques enable deposition of very thin layers, nevertheless constituting a continuous film. This is for example the case of the Metal Organic Chemical Vapor Deposition (MOCVD) technique and of Molecular Beam Epitaxy (MBE) which enables a continuous film of platinum with a thickness of 2.72 nm to be deposited.

Likewise, several techniques enable very thin layers of dielectric material to be deposited. The Atomic Layer Deposition (ALD) technique, which has already been used to form layers with a thickness of about 3 nm for dielectrics such as HfO2 and Al2O3, enables deposition to be performed atomic layer by atomic layer. The MOCVD technique by injection enables thicknesses of a few nanometers (3 or 4 nm) to be achieved for perovskite materials such as STO or BTO. The MBE technique also enables thicknesses in the nanometer range to be achieved for a number of materials, in particular for STO, whereas Ion Beam Sputtering (IBS) enables a layer of STO with a thickness of 10 nm to be achieved.

More generally, the dielectric material could be any material having a dielectric constant higher than 50 and having a breakdown field Ec which increases greatly below a certain thickness e, if this increase of the breakdown field is greater than the associated decrease of the dielectric constant. For a capacitance of pre-determined value and a pre-determined surface S, it can in fact be shown that for the breakdown voltage Vc(FIG. 3) of a capacitor according to FIG. 3 (with n superposed dielectric layers separated by metal intermediate layers) to be greater than the breakdown voltage Vc(FIG. 1) of a capacitor according to FIG. 1, it suffices that, for each dielectric layer, the increase of the breakdown field due to the reduction of its thickness be greater than the decrease of the dielectric constant: E(FIG. 3)/E(FIG. 1)>ε(FIG. 1)/ε(FIG. 3).

The invention is more particularly interesting to increase the breakdown voltage in applications in which the required capacitances are low, for example to form RF decoupling capacitors in mobile phones, typically about 1 pf to 100 pF. In a general manner, with a comparable thickness of dielectric 3 and an equivalent surface, the invention therefore enables capacitances to be achieved that are of the same dielectric value but of higher breakdown voltage, for example twice as high.

1. Thin-film capacitor comprising two electrodes separated by a dielectric formed by superposition of at least two sub-layers of dielectric material, two adjacent superposed dielectric sub-layers being separated by an electrically insulated metal intermediate layer, capacitor wherein the dielectric material has a dielectric constant greater than 50 and a breakdown field which increases greatly below a certain thickness.

2. Capacitor according to claim 1, wherein the dielectric material is perovskite-based and each sub-layer of dielectric material has a thickness smaller than or equal to 50 nm.

3. Capacitor according to claim 2, wherein each sub-layer of dielectric material has a thickness of about 20 nm.

4. Capacitor according to claim 2, wherein each metal intermediate layer has a thickness less than or equal to 20 nm.

5. Capacitor according to claim 2, wherein the metal intermediate layers are made of platinum.

6. Capacitor according to claim 2, wherein the metal intermediate layers are made of gold.
